(19) United States
(12) Patent Application Publication
(10) Pub. No.: US 2018/0066897 A1
(43) Pub. Date: Mar. 8, 2018

(54) VAPOR CHAMBER AND UPPER CASING MEMBER THEREOF

(71) Applicant: TAIWAN MICROLOOPS CORP., New Taipei City (TW)

(72) Inventor: Chun-Hung LIN, New Taipei City (TW)

(21) Appl. No.: 15/260,165

(22) Filed: Sep. 8, 2016

(51) Int. Cl. F28D 15/04; H05K 7/20

(52) U.S. Cl. CPC F28D 15/04; H05K 7/20336

(57) ABSTRACT

In a vapor chamber and its upper casing member, the vapor chamber includes a lower casing, an upper casing member and a working fluid. The upper casing member is engaged and sealed with the lower casing, and a chamber is enclosed between the upper casing member and the lower casing. The upper casing member includes a substrate, plural fins and plural support bodies which are integrally formed with one another. The substrate has an outer surface and an inner wall disposed opposite to each other, and each fin is formed and extended from the outer surface, and each support body is formed and extended from the inner wall. The working fluid is filled in the chamber. Each support body is provided for conducting heat from the lower casing to each fin.

### FIELD OF THE INVENTION

The technical field generally relates to a vapor chamber, more particularly to a vapor chamber and an upper casing assembly applied to a heat source of electronic devices.

### BACKGROUND OF THE INVENTION

As the computing speed of electronic devices increases, the heat generated by the electronic devices becomes increasingly higher. To overcome the large quantity of generated heat, manufacturers have introduced and extensively used a vapor chamber for dissipating the heat. However, the thermal conduction performance, the manufacturing cost, and the level of difficulty of the manufacture of the conventional vapor chamber still have room for improvements.

In general, the conventional vapor chamber comprises an upper casing, a lower casing and a capillary tissue installed in the interior space between the upper casing and the lower casing, wherein the upper casing and the lower casing are welded and engaged with each other, and then a working fluid is filled in the upper casing and the lower casing, and final processes including an air removal process and a sealing process are performed to complete the manufacture of the conventional vapor chamber.

Although such conventional vapor chamber has the thermal conduction performance, its practical application still has the following problems. The vapor chamber has a plurality of support pillars, and each pillar support pillar is provided as means for the deformation of the wall surfaces of the vapor chamber when heated as well as a medium for the heat conduction of the vapor chamber. The conventional support pillars are generally formed in the upper casing or the lower casing of the vapor chamber, so that when heat is conducted through each support pillar to the upper casing or the lower casing, the heat conduction may be interrupted or the performance of heat conduction may be lowered due to the existence of small gaps or a slight manufacturing tolerance.

### SUMMARY OF THE INVENTION

It is a primary objective of this disclosure to provide a vapor chamber using each support body to conduct heat from the lower casing to each fin quickly to increase the speed of the thermal conduction of the vapor chamber and its upper casing member.

To achieve the aforementioned and other objectives, this disclosure provides a vapor chamber, comprising a lower casing, an upper casing member, and a working fluid. The upper casing member and the lower casing are engaged with each other and sealed, and a chamber is enclosed between the upper casing member and the lower casing. The upper casing member comprises a substrate, a plurality of fins, and a plurality of support bodies, which are integrally formed with one another, and the substrate has an outer surface and an inner wall disposed opposite to each other, and each fin is formed and extended from the outer surface, and each support body is formed and extended form the inner wall. The working fluid is filled in the chamber.

To achieve the aforementioned and other objectives, this disclosure further provides an upper casing of the vapor chamber, and the upper casing member comprises a substrate, a plurality of fins, and a plurality of support bodies, which are integrally formed with one another. The substrate has an outer surface and an inner wall disposed opposite to each other, and each fin is formed and extended from the outer surface, and each support body is formed and extended form the inner wall.

This disclosure has the following effects. Since each support body, the substrate, and each fin are integrally formed and made of the same material of a high thermal conductivity, and thus the speed of thermal conduction is increased by the same structure and properties of components of the vapor chamber, so as to improve the thermal conduction performance of the vapor chamber.

### BRIEF DESCRIPTION OF THE DRAWINGS

FIG. 1 is an exploded view of an upper casing member and a lower casing of a vapor chamber of this disclosure;

FIG. 2 is a schematic perspective view of assembling an upper casing member and a lower casing of a vapor chamber of this disclosure;

FIG. 3 is a sectional view of an upper casing member and a lower casing of a vapor chamber of this disclosure;

FIG. 4 is another sectional view of a first preferred embodiment of this disclosure;

FIG. 5 is a sectional view of a second preferred embodiment of this disclosure; and

FIG. 6 is a sectional view of a third preferred embodiment of this disclosure.

### DESCRIPTION OF THE PREFERRED EMBODIMENTS

The technical contents of this disclosure will become apparent with the detailed description of preferred embodiments accompanied with the illustration of related drawings as follows. It is intended that the embodiments and figures disclosed herein are to be considered illustrative rather than restrictive.

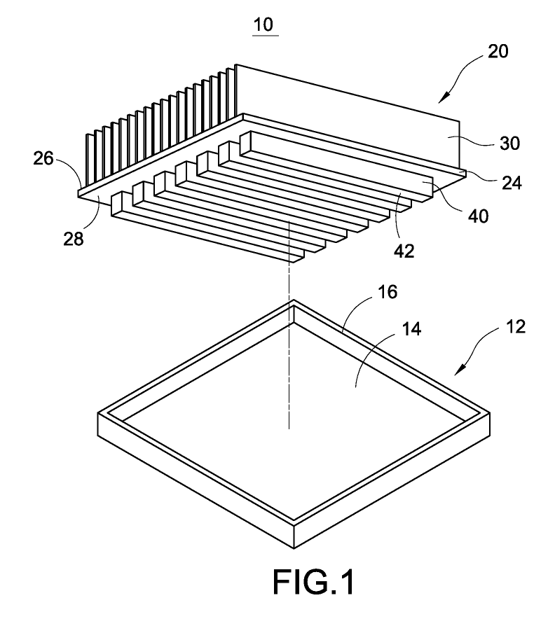

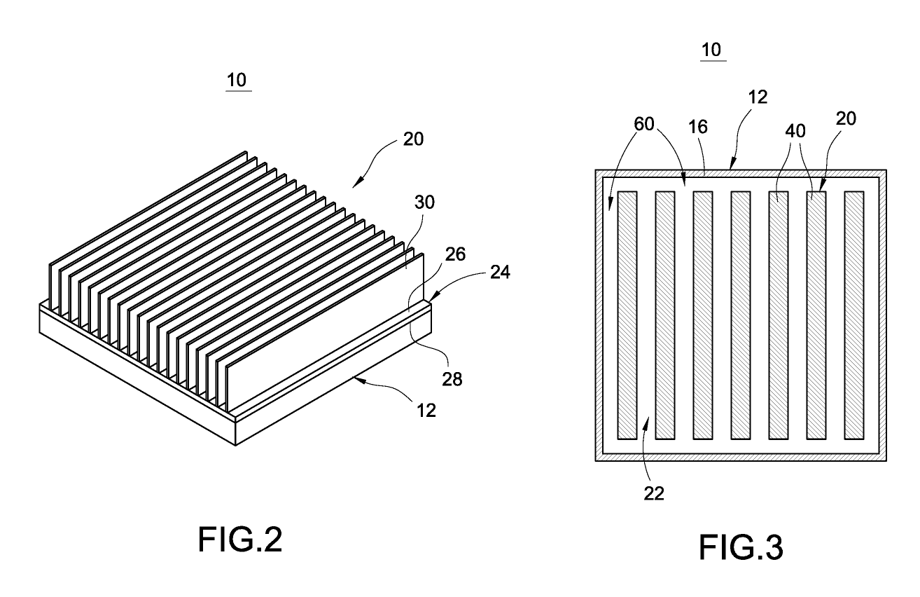

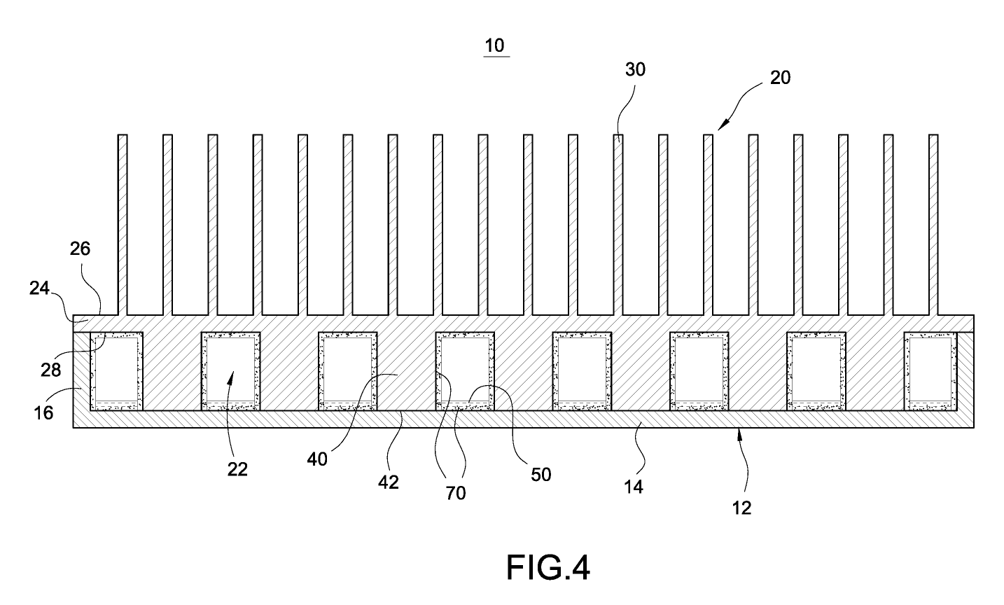

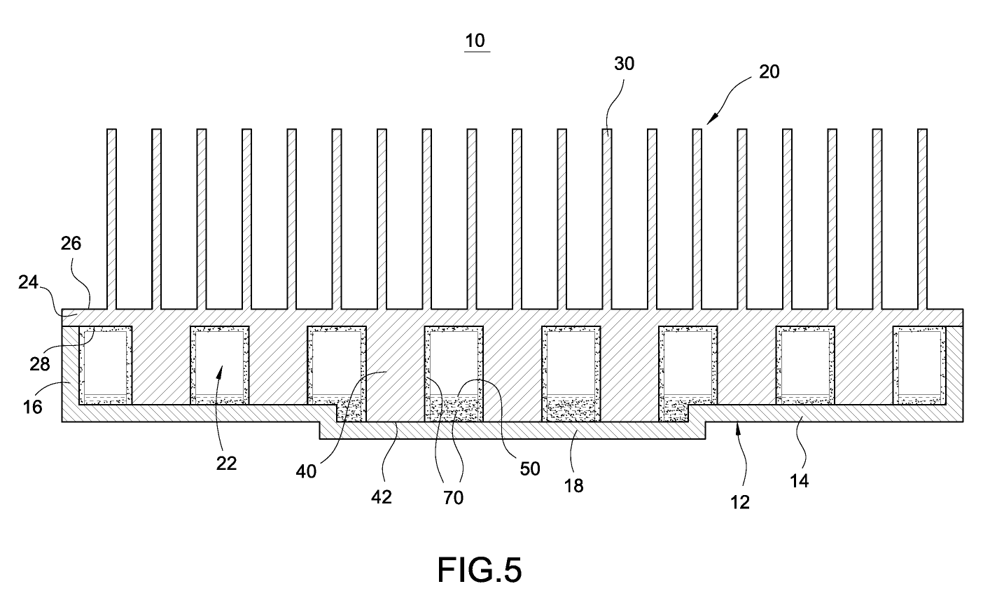

With reference to FIGS. 1 to 4 for a vapor chamber 10 of this disclosure, the vapor chamber 10 comprises a lower casing 12, an upper casing member 20 and a working fluid 50 (as shown in FIG. 4).

In this preferred embodiment, the lower casing 12 is made of copper, aluminum, copper-aluminum alloy, or any other material with good thermal conductivity. The lower casing 12 has a rectangular base plate 14, and a side plate 16 erected from the periphery of the base plate 14 separately. The rectangular base plate 14 is preferably contacted with a heat source (not shown in the figures), such as a chip or a processor for conducting the waste heat produced by the operation of the heat source to the outside of the vapor chamber 10. Of course, the base plate 14 may be in a shape including but not limited to a circular shape or any other appropriate shapes in other preferred embodiments.

The upper casing member 20 is also made of copper, aluminum, copper-aluminum alloy, or any other material with good thermal conductivity. The upper casing member 20 and the lower casing 12 are engaged with each other and closely sealed, and a chamber 22 is enclosed between the upper casing member 20 and the lower casing 12. In this preferred embodiment, the upper casing member 20 comprises a rectangular substrate 24, a plurality of fins 30, and a plurality of support bodies 40, which are integrally formed with one another. The rectangular substrate 24 is preferably configured to be corresponsive to the rectangular base plate 14 of the lower casing 12, and the shape of the rectangular substrate 24 may be changed according to the shape of the lower casing 12.

When the upper casing member 20 is engaged with the lower casing 12, each side plate 16 of the lower casing 12 is attached to the periphery of the substrate 24 of the upper casing member 20, and then sealed by welding or any other appropriate method, so that the chamber 22 is formed and enclosed between the upper casing member 20 and the lower casing 12, and then a liquid-inputting and gas-removing pipe (not shown in the figure) is used to fill the working fluid 50 into the chamber 22, and final operations including gas removal and sealing are performed to complete the manufacture of the vapor chamber 10 of this disclosure.

It is noteworthy that the substrate 21 of this preferred embodiment has an outer surface 26 and an inner wall 28 disposed opposite to each other, and each fin 30 is formed and extended from the outer surface 26, and each support body 40 is formed and extended from the inner wall 28. In the first preferred embodiment as shown in FIG. 4, each fin 30 is preferably erected from the outer surface 26 and formed by extrusion, relieving, or any other appropriate methods may be used for space formation. Each support body 40 is preferably erected from the inner wall 28, and an end surface 42 abuts the base plate 14 of the lower casing 12. Since each support body 40, the substrate 24, and each fin 30 are integrally formed and made of the same material of a high thermal conductivity, therefore the speed of the thermal conduction is increased to improve the thermal conduction performance of the vapor chamber due to the same structure and properties of the components. Therefore, the heat generated by the heat source can be conducted through each support body 40 to each fin 30 at a far end.

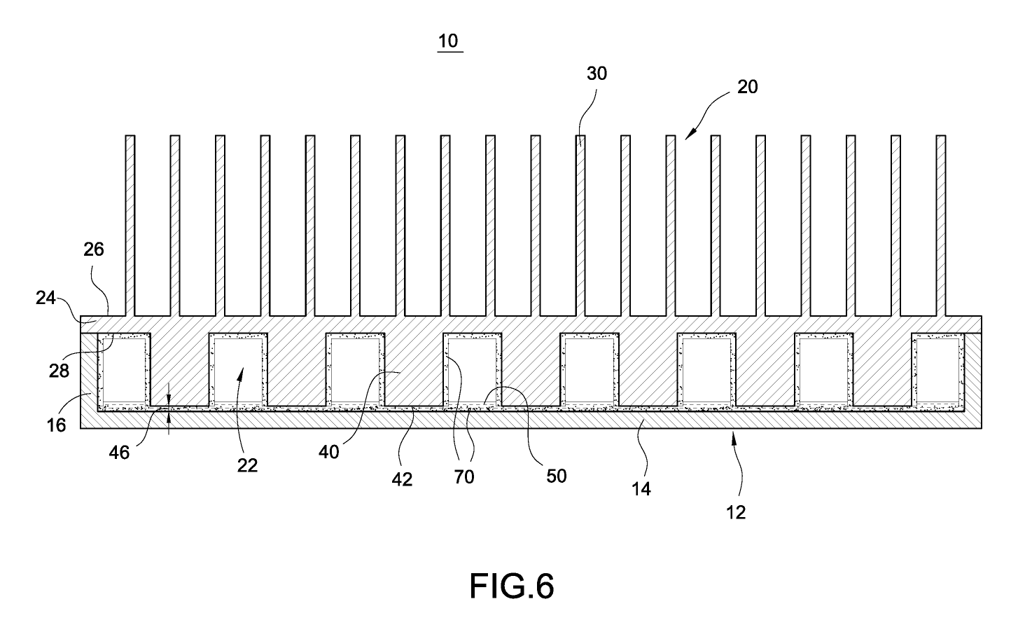

With reference to FIG. 5 for the sectional view of the second preferred embodiment of this disclosure, the lower casing 12 further comprises a recessed portion 18 disposed at a position far away from the support body 40. The recessed portion 18 is preferably configured to be corresponsive to a heat generating component or a heat source (not shown in the figure) and contacted with a surface of the heat generating component or heat source. An end surface 42 of the support body 40 is contacted with the bottom side of the recessed portion 18. In other words, the length of the support body 40 of the recessed portion 18 is greater than the length of each support body 40 not disposed at the recessed portion 18 o achieve the same effect of conducting the heat through each support body 40 to each fin 30 at a far end quickly.

In the preferred embodiment as shown in FIGS. 3 and 4, each support body 40 is preferably in the shape including but not limited to the shape of a long-strip pillar and the long-strip pillars are distributed with an interval apart from one another in the chamber 22. A flow channel 60A is formed between each support body 40 and the plurality of side plates 16 of the lower casing 12 and provided for circulating the working fluid 50. The flow channel 60 is communicated with the chamber 22, so that the working fluid 50 can be circulated in the flow channel 60.

In addition, the vapor chamber 10 of this disclosure further comprises a capillary tissue 70 installed at the base plate 14 of the lower casing 12, and between each support body 40 and the inner wall 28, and on the inner wall of each side plate 16 of the lower casing 12. The working fluid 50 is dispersed quickly under the effect of the chamber 22 or the capillary tissue 70 of each flow channel 60, and through the liquid-state or gas-state conversion of the capillary tissue 70 to conduct the heat to the vapor chamber 10 quickly. In addition, the capillary tissue 70 is a metal mesh, a porous metal powder sinter or any other appropriate structure.

With reference to FIG. 6 for a sectional view of the third preferred embodiment of this disclosure, each support body 40 is erected from the inner wall 28, and a gap 46 is formed between an end surface 42 of each support body 40 and a base plate 14 of the lower casing 12. In other words, the heat can be dispersed by the working fluid 60 of the capillary tissue 70.

The operation of the vapor chamber 10 of this disclosure is as follows. During practical applications of the vapor chamber 10, the base plate 14 of the lower casing 12 is preferably used as a heated portion. In other words, the base plate 14 is directly attached to a heat source of an electronic device (not shown in the figure). Heat is generated during the operation of the heat source, and such heat is conducted to the base plate 12 and dispersed to the liquid-state working fluid 50 in the capillary tissue 70. The liquid-state working fluid 50 is heated and converted into a gas-state working fluid 50, and the gas-state working fluid 50 flows to a cooler inner wall 28 quickly by means of the capillary tissue 70 disposed between each support body 40 and the inner wall 28, and the heat is discharged to the outside through the heat dissipation effect of each fin 30 of the substrate 24 to increase the speed of thermal conduction, so as to improve the thermal conduction performance of the vapor chamber 10.

After the gas-state working fluid 50 is in contact with the capillary tissue 70 of the cooler inner wall 28, the gas-state working fluid 50 is condensed into liquid-state water molecules, and the capillary tissue 70 on both sides of each support body 40 returns the flow to the base plate 14 to perform a thermal circulation, so that the waste heat generated by the heat source can be discharged quickly by the vapor chamber 10.

This disclosure further provides an upper casing member of the vapor chamber, and the upper casing member comprises a substrate 24, a plurality of fins 30, and a plurality of support bodies 40, which are integrally formed with one another. The substrate 24 has an outer surface 26 and an inner wall 28 disposed opposite to each other, and each fin 30 is formed and extended from the outer surface 26, and each support body 40 is formed and extended from the inner wall 28. The upper casing member 20 of this disclosure has been disclosed in the aforementioned embodiment, and thus will not be repeated.

While this disclosure has been described by means of specific embodiments, numerous modifications and variations could be made thereto by those skilled in the art without departing from the scope and spirit of this disclosure set forth in the claims.

What is claimed is:

1. A vapor chamber, comprising:
a lower casing;
an upper casing member, engaged and sealed with the lower casing, and a chamber being enclosed between the upper casing member and the lower casing, and the upper casing member including a substrate, a plurality of fins, and a plurality of support bodies, which are integrally formed with one another, and the substrate having an outer surface and an inner wall disposed opposite to each other, and each the fin being formed and extended from the outer surface, and each support body being formed and extended from the inner wall; and
a working fluid, filled in the chamber.

2. The vapor chamber according to claim 1, wherein each support body is erected from the inner wall, and an end of each support body abuts a base plate of the lower casing.

3. The vapor chamber according to claim 1, wherein each support body is erected from the inner wall, and a gap is formed between an end surface of each support body and a base plate of the lower casing.

4. The vapor chamber according to claim 1, wherein the lower casing further has a recessed portion disposed far away from the support body, and an end surface of the support body is contacted with the bottom side of the recessed portion.

5. The vapor chamber according to claim 1, wherein each fin is erected from the outer surface and formed with an interval apart from another fin by an extrusion or relieving method.

6. The vapor chamber according to claim 1, wherein each support body is in the shape of a long-strip pillar, and each long-strip pillar is distributed with an interval apart from another long-strip pillar in the chamber.

7. The vapor chamber according to claim 1, further comprising a flow channel formed between each support body and the plurality of side plates of the lower casing, and provided for circulating the working fluid.

8. The vapor chamber according to claim 1, further comprising a capillary tissue disposed in the lower casing, and between each support body and the inner wall, and on the inner wall of the plurality of side plates of the lower casing.

9. The vapor chamber according to claim 8, wherein the capillary tissue is a metal mesh or a porous metal powder sinter.

10. An upper casing member of a vapor chamber, comprising a substrate, a plurality of fins, and a plurality of support bodies, which are integrally formed with one another, wherein the substrate has an outer surface and an inner wall disposed opposite to each other, and each fin is formed and extended from the outer surface, and each support body is formed and extended from the inner wall.

11. The upper casing member of a vapor chamber according to claim 10, wherein each support body is erected from the inner wall, and an end surface of each support body abuts a base plate of a lower casing.

12. The upper casing member of a vapor chamber according to claim 10, wherein each support body is erected from the inner wall, and a gap is formed between an end surface of each support body and a base plate of a lower casing.

13. The upper casing member of a vapor chamber according to claim 10, wherein each support body is in the shape of a long-strip pillar, and each long-strip pillar is distributed with an interval apart from another long-strip pillar.

14. The upper casing member of a vapor chamber according to claim 10, wherein each fin is erected from the outer surface, and each fin is formed with an interval apart from another fin by an extrusion or relieving method.

15. The upper casing member of a vapor chamber according to claim 10, further comprising a capillary tissue disposed between each support body and the inner wall.
